(19) United States
(12) Patent Application Publication
(10) Pub. No.: US 2023/0251973 A1
(43) Pub. Date: Aug. 10, 2023

(54) FPGA-Based Parallel Equalization Method

(71) Applicants: HDU Fuyang Electronic Information Research Institute Co., Ltd., Hangzhou City (CN); HangZhou DianZi University, Hangzhou City (CN)

(72) Inventors: Zhiqun CHENG, Hangzhou (CN); Qingran SUN, Hangzhou (CN); Chao LE, Hangzhou (CN)

(21) Appl. No.: 17/960,212

(22) Filed: Oct. 5, 2022

(30) Foreign Application Priority Data
Feb. 9, 2022 (CN) 202210120876.4

(51) Int. Cl. G06F 12/0884; G06F 30/331

(52) U.S. Cl. CPC G06F 12/0884; G06F 30/331

(57) ABSTRACT

A field programmable gate array (FPGA)-based parallel equalization method is provided. The method implements efficient equalization of communication data by means of a parallel pipeline filter structure and through a least mean square (LMS) algorithm capable of dynamically adjusting a step. Firstly, a tap coefficient of an equalization filter is calculated through the LMS algorithm capable of dynamically adjusting an iteration factor. Secondly, the efficiency of FPGA data processing is improved through a multistage pipeline and a multi-channel parallel data processing. According to the present disclosure, in each clock cycle, there are M channels of data inputted into the equalization filter in parallel, and at the same time, there are also M channels of data outputted in parallel, and thus the FPGA can efficiently perform equalization processing on data acquired by a high-speed analog-to-digital converter (ADC) through the parallel pipeline method.

### CROSS REFERENCE TO RELATED APPLICATION

This patent application claims the benefit and priority of Chinese Patent Application No. 202210120876.4, entitled “FPGA-Based Parallel Equalization Method” filed on Feb. 09, 2022, the disclosure of which is incorporated by reference herein in its entirety as part of the present application.

### TECHNICAL FIELD

The present disclosure relates to a field of signal processing in high-speed communications, in particular to a field programmable gate array (FPGA)-based parallel equalization method, which can perform efficient parallel equalization processing on communication data through the FPGA.

### BACKGROUND ART

Equalization, as an important technology in a communication system, is applied not only to analog communications, but also to digital communications. In digital communication and high-speed data transmission systems, to overcome intersymbol interference, reduce influence of amplitude and delay distortion, and increase a transmission rate as much as possible, a channel equalization technology is required. The so-called equalization is to compensate distortion of a channel. At the same time, given the time-variant characteristics of the channel and interference, to achieve efficient data transmission, system parameters must be adjusted by an adaptive technology to automatically track rapid signal changes.

Least mean square (LMS) adaptive equalization is simple to implement and does not require inverse operations of correlation functions and matrices, and therefore has received extensive attention in practical engineering. However, conventional LMS has a low convergence speed due to a fixed iterative step.

Since a sampling frequency of an analog-to-digital converter (ADC) is generally as high as gigabit samples per second (GSPS) but a clock processing frequency of the FPGA is generally only a few hundred megahertz (MHZ), a conventional transversal finite impulse response (FIR) filter in the FPGA cannot achieve efficient processing of large-throughput data.

### SUMMARY

To solve the above problems, an FPGA-based parallel equalization method is provided. On the one hand, the convergence rate is accelerated through an LMS algorithm capable of dynamically adjusting a step; and on the other hand, each filter unit performs efficient parallel equalization processing on data through a multi-stage pipeline and parallel processing of an overall data.

To overcome the defects existing in the conventional art, the technical solutions of the present disclosure are as follows:

An FPGA-based parallel equalization method includes at least the following steps:
step S1: acquiring a current data frame, the data frame including at least a preamble and data information;
step S2: extracting the preamble from the current data frame;
step S3: calculating a step-variable factor µ and an error signal according to the preamble, and then updating a tap coefficient of an equalization filter according to the step-variable factor µ and the error signal;
step S4: acquiring the data information in the data frame, and performing, by the equalization filter, data processing and then parallel outputting on the data information according to the updated tap coefficient until an end of the current data frame; and
step S5: acquiring a next data frame, and repeating step S2 to step S5;
where, in step S4, the equalization filter includes a plurality of filter units arranged in parallel.

In an embodiment, step S3 further includes the following steps:
step S31: acquiring, by a tap coefficient updating module, a local training sequence;
step S32: sending the preamble to the tap coefficient updating module and any one of the filter units at the same time;
step S33: sending y(n) obtained by the filter unit to the tap coefficient updating module, and then calculating an error signal e(n)=d(n)-y(n), which is a difference between a filter output result and the local training sequence; wherein, n is a current moment, d(n) is a desired signal at the current moment, y(n) is a filter output result at the current moment, and e(n) is an error signal at the current moment;
step S34: calculating a step-variable factor µ through the following formula:
$$μ = {\text{c}}_{0} ⋅ {\left|\text{e} \left(\text{n}\right)\right|}^{{α}_{0}} + {\text{c}}_{1} ⋅ {\left|\text{e} \left(\text{n}\right)\right|}^{{α}_{1}} + {\text{c}}_{2} ,$$
where c₀, c₁, α₀, α₁, and c₂ are adjustable coefficients for accelerating iteration;
step S35: calculating the tap coefficient of the equalization filter through the following formula:
$$\text{W} \left(\text{n} + 1\right) = \text{W} \left(\text{n}\right) + 2 μ \text{} \text{e} \left(\text{n}\right) \text{X} \left(\text{n}\right) ,$$
where, W(n) is the tap coefficient of the equalization filter at the current moment, W(n + 1) is the tap coefficient of the equalization filter at a next moment, and X(n) is an input signal at the current moment; and
step S36: updating the error signal according to the tap coefficient of the equalization filter at the next moment, and when the updated error signal does not converge, repeating step S31 to step S36.

In an embodiment, the local training sequence is pre-stored in a non-volatile memory.

In an embodiment, before acquiring the data frame, the tap coefficient of the filter is initialized, a data cache unit is reset, and initial cache data is 0.

In an embodiment, in the step S31, the local training sequence is preamble data which are to be sent by a sending end and is known to a receiving end. After the data are transmitted through a channel, due to intersymbol interference, noise, etc., the received data are inconsistent with the originally sent data. To solve such a problem, it is necessary to find an inverse channel of the channel as much as possible to counteract the influence of the channel on data transmission. A segment of pseudorandom sequence of the data frame (the preamble part of a frame structure) is firstly sent, which is known to a receiver. The receiver passes the received preamble data through a digital filter and changes a tap coefficient of the digital filter for a plurality of times according to an error between an output result and the known preamble data, such that the characteristics of the digital filter are approximately equivalent to those of the inverse channel. Passing the data in the frame structure through this filter is equivalent to passing the data through the inverse channel of the original channel, to counteract the influence of data transmission in the channel.

In an embodiment, in step S4, the data information is stored in a cache unit for being filtered at a next moment and sent to parallel filter units at the same time.

In an embodiment, each of the filter units processes data using a parallel multi-stage pipeline technology; and after a plurality of data to be added are grouped in pairs and stored into data caches, the data in respective groups are added again and then grouped in pairs again to form a multi-stage pipeline architecture until there is only one number in an adding result in the last stage.

In the above technical solution, the preamble of the data frame is first extracted, and the local training sequence and the preamble are sent to the LMS algorithm-based tap coefficient updating module, where a convergence factor for the LMS algorithm is adjustable to accelerate the iteration rate. To increase the iteration rate, an LMS algorithm with an adjustable iteration factor is used in the present disclosure. Since the error is relatively large at the beginning of the iteration, a relatively large iteration step may be used. As the error signal decreases, the iteration step also decreases, that is, µ₀ > µ₁ > µ₂ > ⋯ > µₘ. According to the above principle, µ is a function of an error signal e(n), that is, µ = µ(e(n)), to calculate an appropriate value for each iteration step.

According to the above technical solution, the iterated tap coefficient W(n) of the filter may be obtained, and output of the data through the equalization filter may be expressed as:

$$y \left(k\right) = {\sum }_{i = 0}^{m - 1} w \left(i\right) ⋅ x \left(k - i\right)$$

$$= w \left(0\right) ⋅ x \left(k\right) + w \left(1\right) ⋅ x \left(k - 1\right) + ⋯ + w \left(m\right) ⋅ x \left(k - m + 1\right)$$

It can be known from the above formula that output of a kth point of the equalization filter is not only related to currently inputted x(k), but also related to previous (m-1) input data points. Therefore, to implement multi-channel parallel outputting, as long as information of an input point corresponding to each filter and previous (m-1) input data are known, the output of the multi-channel parallel equalization filter can be implemented. Since it is necessary to know the data of the previous moment relative to the current moment, a data cache unit needs to be introduced to cache the previous data to the next moment for use by the filter. The amount of data that needs to be cached depends on the length of the tap coefficient and the number of parallel data.

Compared with the conventional art, the present disclosure has the following beneficial effects:

1. The convergence rate of the LMS algorithm is accelerated due to the adjustable iteration factor µ.

2. The data throughput is improved by using a reused function module and multi-channel parallel method.

3. A multistage pipeline and data cache method is introduced to optimize a hardware structure and increase the highest clock frequency that the system can reach.

4. The parallel filters in the present disclosure may implement parallel outputting of M channels of data with inputting M channels of data, thereby improving the processing efficiency of data.

### BRIEF DESCRIPTION OF THE DRAWINGS

FIG. 1 is an overall framework diagram of an FPGA-based parallel equalization method according to the present disclosure.

FIG. 2 is a flow block diagram of an FPGA-based parallel equalization method according to the present disclosure.

FIG. 3 shows a simplified frame format of common communication data, which consists of a preamble and several data blocks.

FIG. 4 is an internal structure diagram of a data cache module and eight-channel parallel equalization filter module according to the present disclosure.

FIG. 5 is an internal structure diagram of any one eight-tap filter unit with a pipeline architecture according to the present disclosure.

### DETAILED DESCRIPTION OF THE EMBODIMENTS

The technical solution provided by the present disclosure will be further described below with reference to the accompanying drawings.

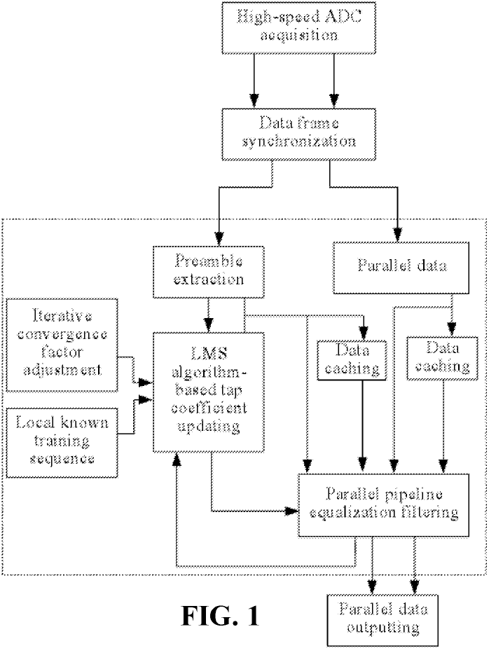

FIG. 1 is an overall framework diagram of an FPGA-based parallel equalization method according to the present disclosure. A parallel pipeline equalization filter module and an LMS algorithm-based tap coefficient updating module are provided. A preamble of a data frame is first extracted, and a local training sequence and the preamble are sent to the LMS algorithm-based tap coefficient updating module, where a convergence factor for the LMS algorithm is adjustable to accelerate the iteration rate.

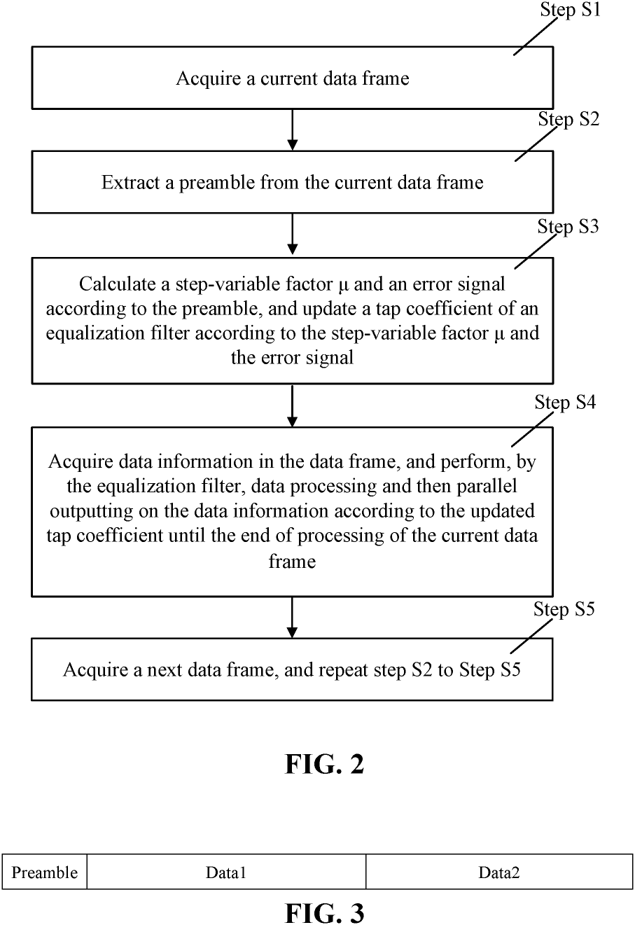

FIG. 2 is a flow block diagram of an FPGA-based parallel equalization method according to the present disclosure. The method includes at least the following steps:
step S1: acquiring a current data frame, where the data frame includes at least a preamble and data information. FIG. 3 shows a simplified frame format of common communication data;
step S2: extracting the preamble from the current data frame;
step S3: calculating a step-variable factor µ and an error signal according to the preamble, and updating a tap coefficient of an equalization filter according to the step-variable factor µ and the error signal;
step S4: acquiring the data information in the data frame, and performing, by the equalization filter, data processing and then parallel outputting on the data information according to the updated tap coefficient until the end of the current data frame; and
step S5: acquiring a next data frame, and repeating step S2 to step S5.

In the step S4, the equalization filter includes a plurality of filter units arranged in parallel.

The step S3 further includes the following steps:
step S31: acquiring, by the tap coefficient updating module, a local training sequence (namely, the preamble part to be sent in the frame structure), where the local training sequence is a pseudorandom sequence agreed with a transmitter-;
step S32: sending the preamble to any one of the filter units and the tap coefficient updating module at the same time;
step S33: sending y(n) obtained by the filter unit to the tap coefficient updating module, and calculating an error signal e(n)=d(n)-y(n), which is a difference between a filter output result and the local training sequence; n is a current moment, d(n) is a desired signal at the current moment, y(n) is a filter output result at the current moment, and e(n) is an error signal at the current moment;
step S34: calculating a step-variable factor µ through the following formula:
$$μ = {\text{c}}_{0} ⋅ {\left|\text{e} \left(\text{n}\right)\right|}^{{α}_{0}} + {\text{c}}_{1} ⋅ {\left|\text{e} \left(\text{n}\right)\right|}^{{α}_{1}} + {\text{c}}_{2} ,$$
where c₀, c₁, α₀, α₁ and c₂ are adjustable coefficients for accelerating iteration;
step S35: calculating the tap coefficient of the equalization filter through the following formula:
$$\text{W} \left(\text{n} + 1\right) = \text{W} \left(\text{n}\right) + 2 μ \text{} \text{e} \left(\text{n}\right) \text{X} \left(\text{n}\right) ,$$
where, W(n) is the tap coefficient of the equalization filter at the current moment, W(n + 1) is the tap coefficient of the equalization filter at a next moment, and X(n) is an input signal at the current moment; and
step S36: updating the error signal according to the tap coefficient of the equalization filter at the next moment, and when the updated error signal does not converge, repeating step S31 to step S36 .

The iterated tap coefficient W(n) of the filter is obtained, and output of the data through the equalization filter may be expressed as:

$$y \left(k\right) = {\sum }_{i = 0}^{m - 1} w \left(i\right) ⋅ x \left(k - 1\right)$$

$$= w \left(0\right) ⋅ x \left(k\right) + w \left(1\right) ⋅ x \left(k - 1\right) + ⋯ + w \left(m\right) ⋅ x \left(k - m + 1\right) ,$$

It can be known from the above formula that output of a kth point of the equalization filter is not only related to currently inputted x(k), but also related to previous (m-1) input data points. Therefore, to implement multi-channel parallel outputting, as long as information of an input point corresponding to each filter and previous (m-1) input data are known, the output of the multi-channel parallel equalization filter can be implemented. Since it is necessary to know the data of the previous moment relative to the current moment, a data cache unit needs to be introduced to cache the previous data to the next moment for use by the filter. The amount of data that needs to be cached depends on the length of the tap coefficient and the number of parallel data.

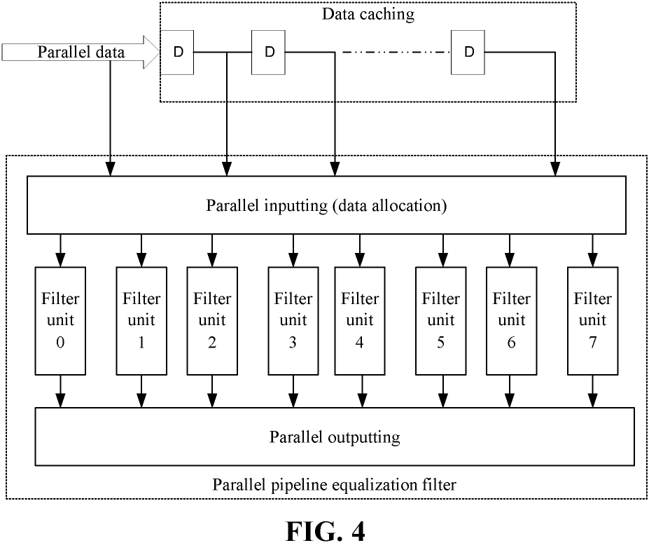

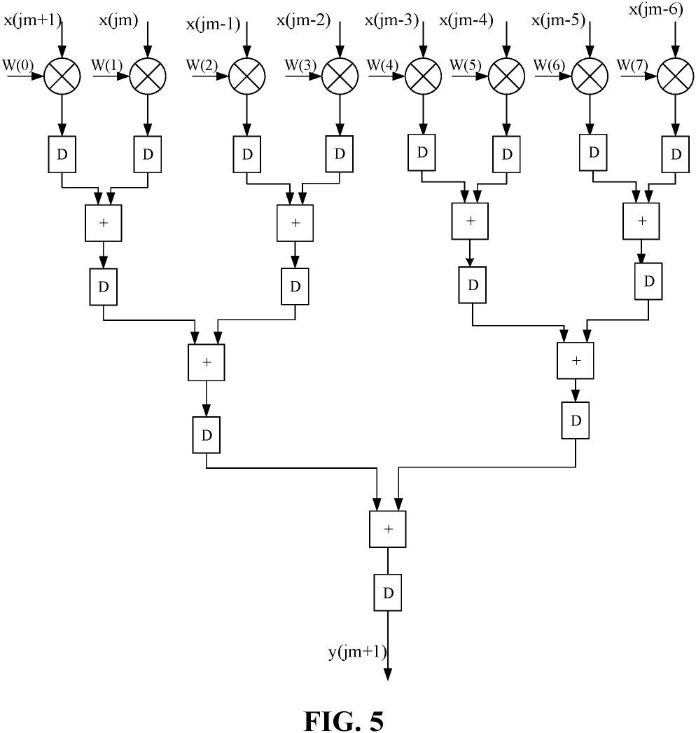

FIG. 4 shows an internal architecture of a parallel pipeline equalization filter module and data cache module in FIG. 1. FIG. 5 is an internal structure diagram of any one of filter units in FIG. 4.

An example where the number m of taps of the equalization filter is 8and eight channels of parallel data acquired by a high-speed ADC are fed to the equalization filter every clock, is taken. A first filter corresponds to x(jm+1), a second filter corresponds to x(jm+2) and so on, where j is an integer. Each filter only needs a point inputted at the current moment and previous (m-1) data points relative to the current moment. Given that x(jm+1) is inputted into the first channel of filter, in order to calculate y(jm+1), in addition to the information of x(jm+1), the information of seven input data from x(jm-6) to x(jm) also need to be obtained by the first channel of filter. Regarding y(jm+2) outputted by the second channel of filter, in addition to the information of x(jm+2), the information of seven input data from x(jm-5) to x(jm+1) also needs to be obtained, and so on. To obtain some data information obtained in the previous clock cycle in the current clock cycle, the data cache unit must be introduced to obtain the data at the current moment and the data at the previous moment at the same time. The amount of data that needs to be cached depends on the length of the tap coefficient and the number of data inputted in parallel per clock cycle.

It is very convenient to implement it on the FPGA. As long as the data acquired each time are stored into the cache unit composed of multiple stages of registers, the parallel data at the current moment and at the previous moment may be obtained at the same time in the current clock cycle. For this example, as long as one stage of register is introduced, eight-channel parallel inputs and outputs may be implemented. It is not difficult to find that the parallel implementation method only changes the input data of each filter, while the internal structure of the filter is completely consistent and may be reused. That is, in the FPGA-based implementation process, the internal structures of 8 parallel equalization filter units are the same, and it only needs to repeat instantiation and change the input interface data.

In addition, in a case that the number of taps of the filter is 8and the conventional transversal filter is configured to calculate the data, on the one hand, it takes 7 clock cycles to add 8 data sequentially; and on the other hand, from the perspective of hardware, this structure affects the highest clock frequency that the system can reach, and this problem becomes more pronounced as the number of taps increases. Therefore, by introducing the structure of multi-stage pipeline, the data is cached through the register, and the data is added in pairs until there is only one datum in the last stage. Since each stage of pipeline is performed in parallel, the operation of the data takes only one clock cycle. The 8-tap filter unit may use a 3-stage pipeline architecture to implement efficient parallel equalization filtering. If there are 2ⁿ taps, there are n stages of pipeline to be added.

The technical solution of the present disclosure will be described below in detail with reference to specific Embodiment 1.

### Embodiment 1

On the basis of the above technical concept of the present disclosure, in this example, the FPGA-based parallel equalization method includes the following several steps:

Step 1: a local training sequence is generated as a file in coe format to be stored in a read only memory (ROM) in advance. The local training sequence (namely, a preamble part in a frame structure) is a pseudorandom sequence agreed with a transmitter.

Step 2: a data cache unit is reset to initialize the cache data to be 0, and a tap coefficient of a filter is initialized.

Step 3: the received preamble data and cached preamble data are sent into any one of the filter units and a tap coefficient updating module at the same time, and the preamble data currently received are cached for use at a next moment.

Step 4: y(n) obtained by the filter unit is sent to the tap coefficient updating module again, corresponding desired signal d(n) is extracted, by the tap coefficient updating module, from the ROM, and an error signal e(n)=d(n)-y(n),which is a difference between a filter output result and the local training sequence, is calculated.

Step 5: a step-variable factor µ is calculated through the following formula:

$$μ = {\text{c}}_{0} ⋅ {\left|\text{e} \left(\text{n}\right)\right|}^{{α}_{0}} + {\text{c}}_{1} ⋅ {\left|\text{e} \left(\text{n}\right)\right|}^{{α}_{1}} + {\text{c}}_{2} ,$$

where c₀, c₁, α₀, α₁, and c₂ are adjustable coefficients for accelerating iteration, which may be adjusted according to the magnitude of the error signal.

Step 6: the tap coefficient of the equalization filter is calculated by the tap coefficient updating module through the following formula:

$$\text{W} \left(\text{n} + 1\right) = \text{W} \left(\text{n}\right) + 2 μ \text{} \text{e} \left(\text{n}\right) \text{X} \left(\text{n}\right) ,$$

where W(n) is the tap coefficient of the equalization filter, X(n) is an input signal, and e(n) is an error signal.

Step 7: the tap coefficient is updated. If the error signal converges, the step 8 is performed, or otherwise, step 3 is returned to.

Step 8: the data currently acquired by the ADC are inputted in parallel, and the data cache module is updated. On the one hand, the cache data are extracted and sent together with the data acquired in this cycle to the parallel equalization filters; and on the other hand, the data in this cycle are sent to the data cache module for being filtered at a next moment.

Step 9: the data are allocated to each filter unit, and each filter unit processes the data using a parallel multistage pipeline technology. As shown in FIG. 5, after a plurality of data to be added are grouped in pairs and stored into data caches, the data in respective groups are added again and then grouped in pairs again to form a multi-stage pipeline architecture until the last stage.

Step 10: a filter operation of the data is completed at the same time, and the data are outputted in parallel. The steps 8, 9 and 10 are repeated until the end of one frame of data.

Step 11: the step 2 is performed if a next frame of data need to be processed.

The above technical solution can improve the equalization processing efficiency of communication data.

The above description of examples is merely provided to help illustrate the method of the present disclosure and a core idea thereof. It should be noted that several improvements and modifications may be made by persons of ordinary skill in the art without departing from the principle of the present disclosure, and these improvements and modifications should also fall within the scope of the present disclosure.

The above description of the disclosed embodiments enables those skilled in the art to achieve or use the present disclosure. Various modifications to these embodiments are readily apparent to those skilled in the art, and the generic principles defined herein may be practiced in other embodiments without departing from the spirit or scope of the present disclosure. Thus, the present disclosure is not limited to the examples shown herein but falls within a widest scope consistent with the principles and novel features disclosed herein.

What is claimed is:

1. A field programmable gate array (FPGA)-based parallel equalization method, comprising:
step S1: acquiring a current data frame, the data frame comprising at least a preamble and data information;
step S2: extracting the preamble from the current data frame;
step S3: calculating a step-variable factor µ and an error signal according to the preamble, and then updating a tap coefficient of an equalization filter according to the step-variable factor µ and the error signal;
step S4: acquiring the data information in the data frame, and performing, by the equalization filter, data processing and then parallel outputting on the data information according to the updated tap coefficient until an end of the current data frame; and
step S5: acquiring a next data frame, and repeating step S2 to step S5;
wherein, in step S4, the equalization filter comprises a plurality of filter units arranged in parallel.

2. The FPGA-based parallel equalization method according to claim 1, wherein step S3 further comprises:
step S31: acquiring, by a tap coefficient updating module, a local training sequence;
step S32: sending the preamble to the tap coefficient updating module and any one of the filter units at the same time;
step S33: sending y(n) obtained by the filter unit to the tap coefficient updating module, and then calculating an error signal e(n)=d(n)-y(n), which is a difference between a filter output result and the local training sequence; wherein, n is a current moment, d(n) is a desired signal at the current moment, y(n) is a filter output result at the current moment, and e(n) is an error signal at the current moment;
step S34: calculating a step-variable factor µ through the following formula:
$$\text{μ} = {\text{c}}_{0} ⋅ {\left|\text{e} \left(\text{n}\right)\right|}^{{\text{α}}_{0}} + {\text{c}}_{1} ⋅ {\left|\text{e} \left(\text{n}\right)\right|}^{{\text{α}}_{1}} + {\text{c}}_{2} ,$$
wherein c₀, c₁, α₀, α₁, and c₂ are adjustable coefficients for accelerating iteration;
step S35: calculating the tap coefficient of the equalization filter through the following formula:
$$\text{W} \left(\text{n + 1}\right) = \text{W} \left(\text{n}\right) + 2 \text{μ} \text{e} \left(\text{n}\right) \text{X} \left(\text{n}\right)$$
wherein, W(n) is the tap coefficient of the equalization filter at the current moment, W(n + 1) is the tap coefficient of the equalization filter at a next moment, and X(n) is an input signal at the current moment; and
step S36: updating the error signal according to the tap coefficient of the equalization filter at the next moment, and when the updated error signal does not converge, repeating step S31 to step S36.

3. The FPGA-based parallel equalization method according to claim 2, wherein the local training sequence is pre-stored in a non-volatile memory.

4. The FPGA-based parallel equalization method according to claim 2, wherein before acquiring the data frame, a data cache unit is reset, and initial cache data is 0.

5. The FPGA-based parallel equalization method according to claim 2, wherein in the step S4, current data information is stored in the cache unit for being filtered at a next moment, and at the same time, the current data information and data information cached at a previous moment are extracted and sent to parallel filter modules.

6. The FPGA-based parallel equalization method according to claim 2, wherein each of the filter units processes data using a parallel multi-stage pipeline technology; wherein, after a plurality of data to be added are grouped in pairs and stored into data caches, the data in respective groups are added again and then grouped in pairs again to form a multi-stage pipeline architecture until there is only one number in a last stage.

7. The FPGA-based parallel equalization method according to claim 2, wherein the iterated tap coefficient W(n) of the equalization filter is obtained, a number of taps is m, and output of the data through the equalization filter is expressed as:
$$y \left(k\right) = {\sum }_{i = 0}^{m - 1} w \left(i\right) ⋅ x \left(k - i\right)$$
$$= w \left(0\right) ⋅ x \left(k\right) + w \left(1\right) ⋅ x \left(k - 1\right) + ⋯ + w \left(m\right) ⋅ x \left(k - m + 1\right) ,$$
wherein output at a kth point of the equalization filter is not only related to currently inputted x(k), but also related to previous (m-1) input data points; and as long as information of an input point corresponding to each filter and previous (m-1) input data are obtained, the output of a multichannel parallel equalization filter is implemented.

8. The FPGA-based parallel equalization method according to claim 1, wherein in each clock cycle, there are M channels of data inputted into the equalization filter in parallel, and at the same time, there are also M channels of data outputted in parallel.
